(19) United States
(12) Patent Application Publication
(10) Pub. No.: US 2024/0114692 A1
(43) Pub. Date: Apr. 4, 2024

(54) INVERTED FERROELECTRIC AND ANTIFERROLECETRIC CAPACITORS

(71) Applicant: Intel Corporation, Santa Clara, CA (US)

(72) Inventors: Nazila Haratipour, Portland, OR (US); Uygar E. Avci, Portland, OR (US); Vachan Kumar, Hillsboro, OR (US); Hai Li, Portland, OR (US); Yu-Ching Liao, Portland, OR (US); Ian Alexander Young, Olympia, WA (US)

(73) Assignee: Intel Corporation, Santa Clara, CA (US)

(21) Appl. No.: 17/958,395

(22) Filed: Oct. 1, 2022

(51) Int. Cl. H01L 27/11502; G11C 11/22; H01L 27/108; H01L 29/94

(52) U.S. Cl. CPC H01L 27/11502; G11C 11/221; G11C 11/223; H01L 27/1087; H01L 29/945

(57) ABSTRACT

Inverted pillar capacitors that have a U-shaped insulating layer are oriented with the U-shaped opening of the insulating layer opening toward the surface of the substrate on which the inverted pillar capacitors are formed. The bottom electrodes of adjacent inverted pillar capacitors are isolated from each other by the insulating layers of the adjacent electrodes and the top electrode that fills the volume between the electrodes. By avoiding the need to isolate adjacent bottom electrodes by an isolation dielectric region, inverted pillar capacitors can provide for a greater capacitor density relative to non-inverted pillar capacitors. The insulating layer in inverted pillar capacitors can comprise a ferroelectric material or an antiferroelectric material. The inverted pillar capacitor can be used in memory circuits (e.g., DRAMs) or non-memory applications.

### BACKGROUND

Pillar-type capacitors are used in dynamic random-access memories (DRAMs) and embedded DRAMs. Pillar-type capacitors can provide a greater capacitance density per unit area relative to planar capacitors.

### BRIEF DESCRIPTION OF THE DRAWINGS

FIG. 1A is a cross-sectional view of example non-inverted pillar capacitors.

FIG. 1B illustrates an example memory application of the non-inverted pillar capacitors on FIG. 1A.

FIG. 2A is a cross-sectional view of example inverted pillar capacitors.

FIG. 2B illustrates an example memory application of the inverted pillar capacitors of FIG. 2A.

FIGS. 3A-3L illustrate a simplified process flow for forming inverted pillar capacitors.

FIGS. 4A-4C illustrate top-down views of a simplified process flow for implementing a first plate line scheme in a memory array employing inverted pillar capacitors.

FIGS. 5A-5C illustrate top-down views of a simplified process flow for implementing a second plate line scheme in a memory array employing inverted pillar capacitors.

FIG. 6 is an example method of forming an inverted pillar capacitor.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIGS. 9A-9D are perspective views of example planar, FinFET, gate-all-around, and stacked gate-all-around transistors.

FIG. 10 is a cross-sectional side view of an integrated circuit device assembly that may include a microelectronic assembly, in accordance with any of the embodiments disclosed herein.

FIG. 11 is a block diagram of an example electrical device that may include a microelectronic assembly, in accordance with any of the embodiments disclosed herein.

### DETAILED DESCRIPTION

Disclosed herein are pillar-type capacitors (pillar capacitors) comprising a ferroelectric or antiferroelectric insulating layer that have an inverted structure relative to existing pillar capacitors. A ferroelectric material is a material that exhibits, over some range of temperatures, a spontaneous electric polarization (displacement of positive and negative charges from their original position), that can be reversed or reoriented by the application of an electric field. Because the displacement of the charges in ferroelectric materials can be maintained for some time even in the absence of an electric field, such materials may be used to implement non-volatile memory cells. For example, if the logical state of a memory cell is represented by the orientation of the electric polarization of a ferroelectric material (e.g., the ferroelectric insulating layer of a ferroelectric capacitor), the orientation of the electric polarization of the ferroelectric material in a first direction can represent a first logical state of the memory cell and the orientation of the electric polarization of the ferroelectric material in a second direction that is reversed (or opposite) from the first direction can represent a second logical state of the memory cell. Ferroelectric memories comprising ferroelectric capacitors have the potential for adequate non-volatility, short programming time, low power consumption, high endurance, and high-speed writing. In addition, ferroelectric memories comprising ferroelectric capacitors may be manufactured using processes that are compatible with existing complementary metal-oxide-semiconductor (CMOS) manufacturing technology. Thus, these types of memories have emerged as promising candidates for memories in next-generation manufacturing processes.

The ferroelectric capacitors described herein can be utilized in memories (ferroelectric memories), such as embedded DRAM (in which the ferroelectric capacitors are embedded in the metallization stack of an integrated circuit component) or other high-density memories. The ferroelectric capacitors can also be used as capacitors in non-memory applications, such as in analog circuitry.

Capacitors described herein having an antiferroelectric insulating layer comprise an antiferroelectric material. Certain antiferroelectric materials offer higher permittivities, which make them an attractive candidate for capacitor use in high-density memories. Some antiferroelectric materials also have a ferroelectric phase under certain conditions (such as when a sufficient electric field is applied across an antiferroelectric layer), which can make such antiferroelectric materials attractive for use in non-volatile applications.

An antiferroelectric material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern). This can be contrasted with ferroelectric materials, which may assume a state in which all of the dipoles point in the same direction.

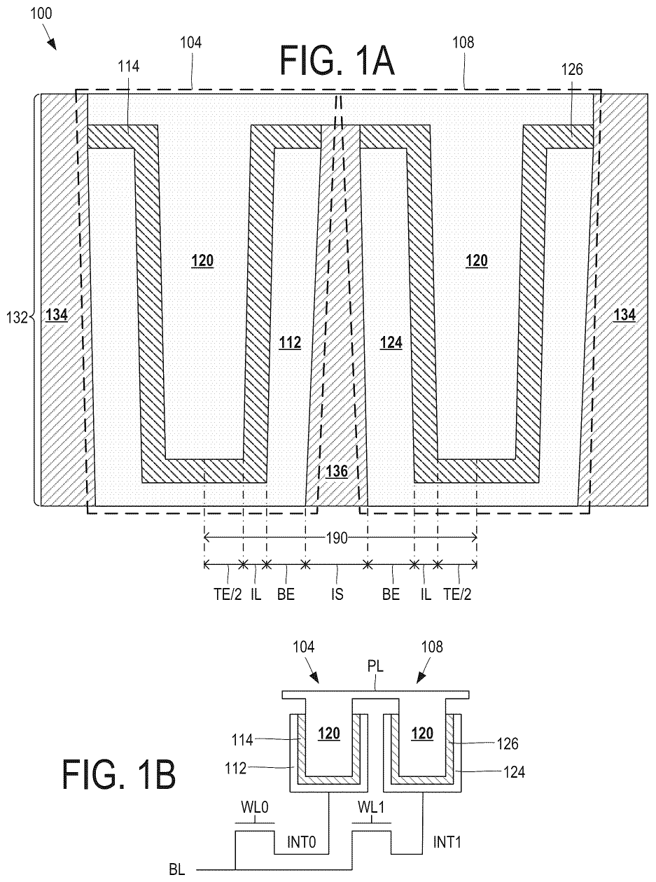

The ferroelectric and antiferroelectric pillar capacitors described herein have an inverted structure, wherein the U-shaped capacitor opens toward the surface of the substrate upon which the capacitors are formed provide for an improved capacitor density in memory applications. In the inverted pillar capacitor structure, the bottom electrodes of adjacent capacitors can be isolated without the need for an intervening dielectric region between adjacent pillars to isolate the bottom electrodes, as can be the case for “non-inverted” capacitors (e.g., those illustrated in FIGS. 1A-1B). Rather, the shared top electrode and the insulating layers of adjacent capacitors isolate bottom electrodes in adjacent inverted pillar capacitors.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the sidewalls of a top electrode, bottom electrode, or an insulating layer of capacitor described as being substantially vertical can be within +/−20 degrees of vertical.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

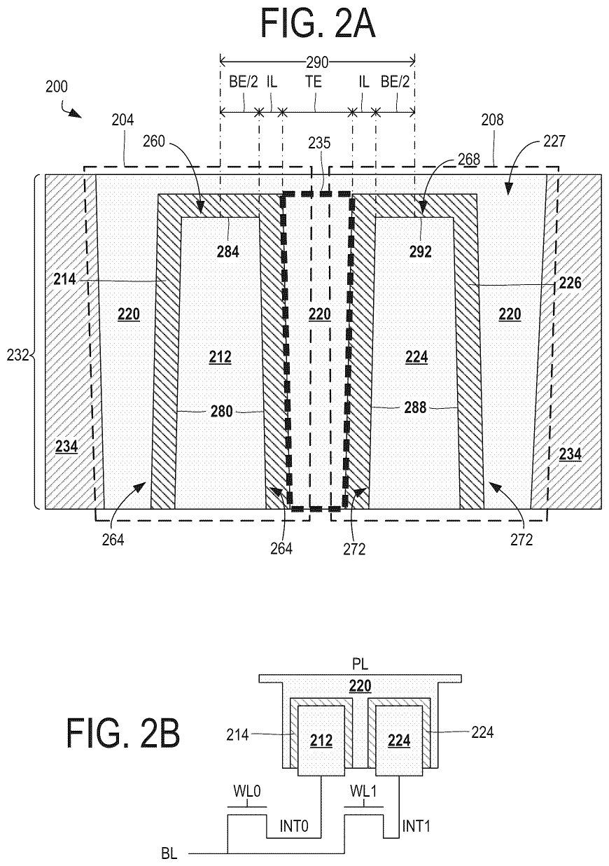

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, with reference to FIG. 2A, the top electrode 220 is located on bottom electrodes 212 and 224 with intervening insulating layers 214 and 226. In another example, pillars referenced as being located on a substrate can have one or more metallization layers positioned the pillars and a surface of the substrate (such as may be the case in an embedded DRAM application).

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

FIG. 1A is a cross-sectional view of example non-inverted pillar capacitors. The structure 100 comprises adjacent capacitors 104 and 108. Capacitor 104 comprises bottom electrode 112, insulating layer 114, and top electrode 120. Capacitor 108 comprises bottom electrode 124, insulating layer 126, and the top electrode 120, which is shared with the capacitor 104. The bottom electrodes (112, 124) and the top electrode 120 comprise a metal and the insulating layers (114, 126) comprise a electrically material, such as a ferroelectric material or an antiferroelectric material. The capacitors 104 and 108 are located in a dielectric layer 132 comprising a dielectric material 134. The bottom electrodes (112, 124) and the insulating layers (114, 126) of the adjacent capacitors 104 and 108 are separated by an isolation region 136 of the dielectric material 134. The bottom electrodes 112, 124 and insulating layers 114, 126 are U-shaped. Each of the insulating layers 116 and 126 comprise a pair of sidewalls joined at the bottom by a connecting portion. The capacitors 104 and 108 are considered “non-inverted” as the U-shape of the capacitors open away from the substrate (not shown in FIG. 1A) on which the capacitors 104 and 108 are formed.

FIG. 1B illustrates an example memory application of the non-inverted pillar capacitors on FIG. 1A. Capacitors 104 and 108 are utilized as the storage capacitors in adjacent memory cells. The memory cells have a common bit line (BL) and are controlled by separate word lines (WL0, WL1). The bottom electrodes 112 and 124 are tied to the storage nodes INTO and INTI of the memory cells, respectively, and the common top electrode 120 is tied to the plate late (PL) of the memory cells.

FIG. 2A is a cross-sectional view example inverted pillar capacitors. The structure 200 comprises adjacent capacitors 204 and 208. Capacitor 204 comprises bottom electrode 212, insulating layer 214, top electrode 220. The bottom electrode 212, which is in the shape of a pillar, a top surface 260 and outer surface 264. The insulating layer 214 is positioned between the bottom electrode 212 and the top electrode 220. Capacitor 208 comprises bottom electrode 224, insulating layer 226, and the top electrode 220, which is shared with capacitor 208. The bottom electrode 224, which is also in the shape of a pillar, comprises a top surface 268 and an outer surface 272. Insulating layer 226 is positioned between the bottom electrode 224 and the top electrode 220.

The bottom electrodes 212 and 224 and insulating layers 214 and 226 are U-shaped, resulting in U-shaped capacitors 204 and 208. Each of the insulating layers comprises a pair of sidewalls joined at the top by a connecting portion. Capacitor 204 comprises sidewalls 280 joined by a top portion 284 and capacitor 208 comprises sidewalls 288 joined by a top portion 292. The capacitors 204 and 208 are considered “inverted” as the U-shape of the capacitors opens toward the substrate (not shown in FIG. 2A) on which the capacitors 204 and 208 are formed.

The capacitors 204 and 208 are located in a recess 227 of a dielectric layer 232 that comprises a dielectric material 234. The top electrode substantially fills the portion of the recess 227 filled by the bottom electrodes (212, 224) and insulating layers (214, 226). The bottom electrodes (212, 224) are isolated from each by the insulating layers (214, 226) and the top electrode 220, which comprises a volume 235 between the capacitors 204 and 208. That is, the top electrode 220 substantially fills the region between the adjacent capacitors 204 and 208. Put another way, there is no region of dielectric material between the adjacent capacitors 204 and 208. Adjacent inverted pillar capacitors (204, 208) occupy less space than adjacent non-inverted pillar capacitors (104, 108) because of the absence of an isolation region of dielectric material between the capacitors to isolate the bottom electrodes (212, 224).

The reduction in area made possible by the use of inverted pillar capacitors over non-inverted pillar capacitors is represented by the difference in the capacitor pitches 190 and 290 in FIGS. 1A and 2A, respectively. The capacitor pitch 190 of the non-inverted capacitors is TE/2+IL+BE+DE+BE+IL+TE/2, which can be simplified as TE+2IL+2BE+DE, where TE, IL, BE, and DE are widths of the top electrode 120, the insulating layers (114, 126), the bottom electrodes (112, 124), and the dielectric isolation region 136 between the capacitors. The capacitor pitch 290 of the inverted cells is BE/2+IL+TE+IL+BE/2, which simplifies to BE+2IL+TE. Thus, the area savings by use of inverted pillar capacitors of non-inverted pillar capacitors is proportional to the difference in the capacitor pitches (TE+2IL+2BE+DE)−(BE+2IL+TE)=BE+DE, or, the width of a bottom electrode plus the width of the isolation dielectric region between adjacent non-inverted pillar capacitors.

The different layers and structures in the structure 200 can comprise the following materials and dimensions. The bottom electrodes (212, 224) can comprise copper, tungsten, nickel, molybdenum, titanium nitride (TiN), other metal or alloy, or other suitable conductive material. The top electrode 220 can comprise copper, tungsten, nickel, molybdenum, titanium nitride (TiN), other metal or alloy, or other suitable conductive material. The substrate upon which the capacitors are located can be any substrate described or referenced herein, such as a substrate comprising silicon.

An interlayer dielectric (ILD) or any other dielectric layer upon or within which (such as in a recess of a dielectric layer) inverted capacitors may be formed can be any suitable nitride or oxide, such as silicon dioxide (SiO₂, which is a material that comprises silicon and oxygen), carbon-doped (C-doped) silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen), or silicon nitride (Si₃N₄, which is a material that comprises silicon and nitrogen).

In some embodiments. the insulating layer (214, 226) comprises a ferroelectric material. In such embodiments, the ferroelectric material can be any suitable ferroelectric, such as a perovskite ferroelectric. For example, the insulating layer of an inverted pillar capacitor may comprise barium titanate (BaTiO₃ or BTO), bismuth ferrite (BiFeO₃ or BFO), or lanthanum-doped bismuth iron oxide (Bi₁₋ₓLaₓ)FeO₃ or LBFO). In other embodiments, the ferroelectric material may be a different material, such as lead zirconate titanate (Pb(ZrₓTi₁₋ₓ)O₃ or PZT), lead niobate zirconate titanate ((Pb₁₋ₓNbₓ)(Zr_{1-y}Ti_{y})O₃ or PNZT), lead lanthanum zirconate titanate ((Pb₁₋ₓLaₓ)(Zr_{1-y}Ti_{y})O₃ or PLZT), lanthanum bismuth ferrite (LaₓBi₁₋ₓFeO₃ or LaBFO), bismuth iron cobaltate (BiFe₁₋ₓCoₓO₃), lithium or potassium niobate (LiNbO₃ or KNbO₃), CaNbTi₂O₆, Pb₂BiNbO₆, Ca₃Nb₂N₂O₅, Bi₄Ti₃O₁₂, Ba(Hf,Ti)O₃, (Ba,Ca)(ZrTi)O₃, GdFeO₃, (Gd,La)FeO₃, etc., and combinations thereof.

In embodiments where the insulating layers (214, 226) comprises an antiferroelectric material, the antiferroelectric material may include one or more materials that exhibit sufficient antiferroelectric behavior even at thin dimensions as typically used in integrated circuit components. Some examples of such materials include materials including hafnium (Hf) and oxygen (O) (e.g., hafnium oxide), such as materials including Hf, O, and zirconium (Zr) (e.g., hafnium zirconium oxide (HfZrO), also referred to as HZO), and hafnium oxide doped with one or more of silicon (Si), aluminum (Al), yttrium (Y), gadolinium (Gd), germanium (Ge), lead (Pb), zirconium (Zr), titanium (Ti), tin (Sn), strontium (Sr), lanthanum (La), or niobium (Nb), at the appropriate dopant concentrations. Hafnium zirconium oxide (HfZrO) and the other doped hafnium oxide materials listed above are ferroelectric at dopant concentrations at about 50% and below, begin exhibiting antiferroelectric-like behavior at dopant concentrations of about 50% and become more antiferroelectric as the dopant concentration (zirconium, silicon, aluminum, etc.) approaches 100%. In various embodiments, the antiferroelectric material may include one or more of hafnium oxide, hafnium zirconium oxide, zirconium oxide, doped hafnium oxide with doping of Si, Al, Y, Gd, Ge, lead zirconate, (Pb,Ba)ZrO₃, (Pb,Sr)ZrO₃, (Pb,La)(Zr_{1-y}Ti_{y})O₃, (Pb_{0.97}La_{0.02})(Zr,Sn,Ti)O₃ and Pb_{0.99}(Zr,Sn,Ti)_{0.98}Nb_{0.02}O₃. However, in other embodiments, any other materials which exhibit antiferroelectric behavior at thin dimensions may be used as the antiferroelectric material in an insulating layer. In some embodiments, the insulating layer of an inverted pillar capacitor can have a thickness in the range of 1-45 nanometers, including all values and ranges therein (e.g., between 1 and 25 nanometers, or between 1 and 10 nanometers).

Although various layers and/or features of the capacitors 204 and 208 are shown as having a vertical taper (such as sidewalls 280, 288), in some embodiments, these layers and/or features do not have a taper. That is, they are substantially vertical.

FIG. 2B illustrates an example memory application of the inverted pillar capacitors of FIG. 2A. Capacitors 204 and 208 are utilized as storage capacitors in adjacent memory cells. The memory cells share a common bit line (BL) and are controlled by separate word lines (WL0, WL1). The bottom electrodes 212 and 224 are tied to the storage nodes INTO and INTI of the memory cells, respectively, and the top electrode 220 is tied to the plate late (PL) of the memory cells.

Although the capacitors 204 and 208 are shown in FIG. 2A as having physically separate portions of an insulating layer as their insulating layer, in some embodiments, an insulating layer covering a plurality of pillars can be continuous. After formation of a recess in a dielectric layer and before formation of a top electrode for the pillar capacitors located on the recess, an insulating layer can be formed that encompasses the top and outer surfaces of the pillars, and the inner and bottom surfaces of the recess, including the bottom surfaces between adjacent pillars.

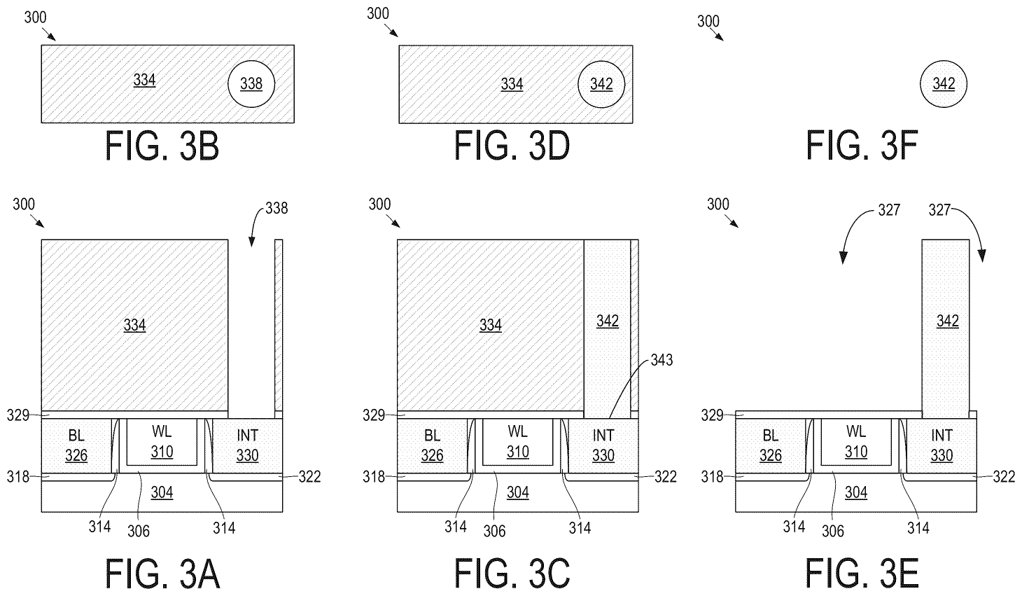

FIGS. 3A-3L illustrate a simplified process flow for forming inverted pillar capacitors. FIGS. 3A-3L illustrate top and cross-sectional view of the simplified process flow at various steps. FIGS. 3A and 3B illustrate cross-sectional and top views, respectively, of a structure after a transistor has been formed on a substrate and an etch made in a dielectric layer above the transistor to form a hole for a pillar (bottom electric) of an inverted capacitor. The transistor and inverted capacitor are part of a memory cell.

The structure 300 comprises a substrate 304 upon which a gate dielectric layer 306, a gate metal region 310, and gate spacers 314 have been formed. Source and drain regions 318 and 322, which comprise one or more n-type or p-type dopants have been formed in surface regions of the substrate. Contacts 326 and 330 contact the source and drain regions 318 and 322, which will operate as the bitline (BL) and storage node (INT) of the memory cell. The transistor gate operates as the word line (WL) of the memory cell. An etch stop layer 329 is located on the contacts (326, 330) and the gate metal region 310. A dielectric layer 334 has been formed on the etch stop layer 329 and a hole 338 has been etched in the dielectric layer 334

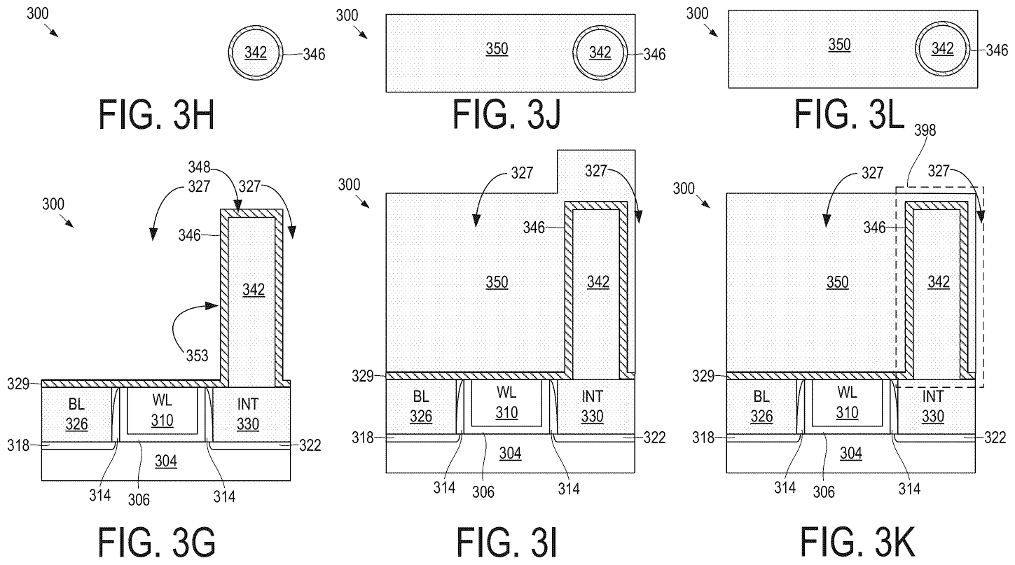

FIGS. 3C and 3D illustrate cross-sectional and top views, respectively, of the structure 300 after filling the hole 338 with a metal to form a pillar 342 that will operate as the bottom electrode of the inverted pillar capacitor. The pillar 342 comprises a metal, such as any of the metal described or referenced herein as being used for an electrode of a capacitor. A base 343 of the pillar 342 is located on and conductively coupled to the contact 330 that is to operate as the storage node of the memory cell. FIGS. 3E and 3F illustrate cross-sectional and top views, respectively, of the structure 300 after etching of the dielectric layer 334 to form a recess 327 in the dielectric layer, the pillar 342 being located in the recess 327. FIGS. 3G and 3H illustrate cross-sectional and top views, respectively, of the structure 300 after formation of an insulating layer 346 on the pillar 342 and the etch stop layer 329. The insulating layer 346 can comprise a ferroelectric material or an antiferroelectric material and encompasses a top surface 348 and an outer surface 353 of the pillar 342. FIGS. 31 and 3J illustrate cross-sectional and top views, respectively, of the structure 300 after formation of a metal layer 350 that will operate as the top electrode of the inverted pillar capacitor and the plate line (PL) of the memory cell. The metal layer 350 is located on the top surface 348 and the outer surface 353 of the pillar 342, with the insulating layer 346 positioned between the pillar 342 and the metal layer 350. As stated above in regard to FIG. 2A, the metal layer 350 substantially fills the recess 327 such that a volume between adjacent pillars in the recess is filled by the metal layer. FIG. 4C (in addition to FIG. 2A) illustrates this feature. FIG. 4C illustrates the metal layer 450 (the top electrode of the capacitors) substantially filling a volume 435 between adjacent capacitors. FIGS. 3K and 3L illustrate cross-sectional and top views, respectively, of the structure 300 after polishing/etching of the metal layer 350. The resulting pillar capacitor 398 has a U-shape that is inverted as the open end of the U-shape opens toward the substrate 304.

Although a planar FET is illustrated in the simplified process flow illustrated in FIGS. 3A-3L, inverted pillar capacitors can be formed in a process flow in which any transistor type described or referenced herein may be fabricated, such as a FinFET or GAAFET.

FIGS. 4A-4C illustrate top-down views of a simplified process flow for implementing a first plate line scheme in a memory array employing inverted pillar capacitors. FIGS. 4A-4C illustrate a structure 400 in which a two-by-three array of inverted pillar capacitors are to be formed. The capacitors are part of a memory array with the bottom electrode (pillar portion) of each capacitor to operate as the storage node for a memory cell and the top electrode to operate as a plate line common to all six memory cells. FIG. 4A illustrates the structure 400 after formation of pillars 452 in a dielectric 434. FIG. 4A illustrates the same step in the process flow illustrated in FIGS. 3A-3L as FIG. 3D. FIG. 4B illustrates the structure 400 after an etch of the dielectric 434 and formation of an insulating layer 446 for the capacitors, and before formation of the metal layer that will form top electrodes for the capacitors in the array. FIG. 4B illustrates the same step in the process flow illustrated in FIGS. 3A-3L as FIG. 3H. FIG. 4C illustrates the structure 400 after formation of the metal layer 450 forming the top electrode for the capacitors in the array. All six capacitors in the two-by-three array share a top electrode and thus, the same plate line. FIG. 4C illustrates the same step in the process flow illustrated in FIGS. 3A-3L as FIG. 3L.

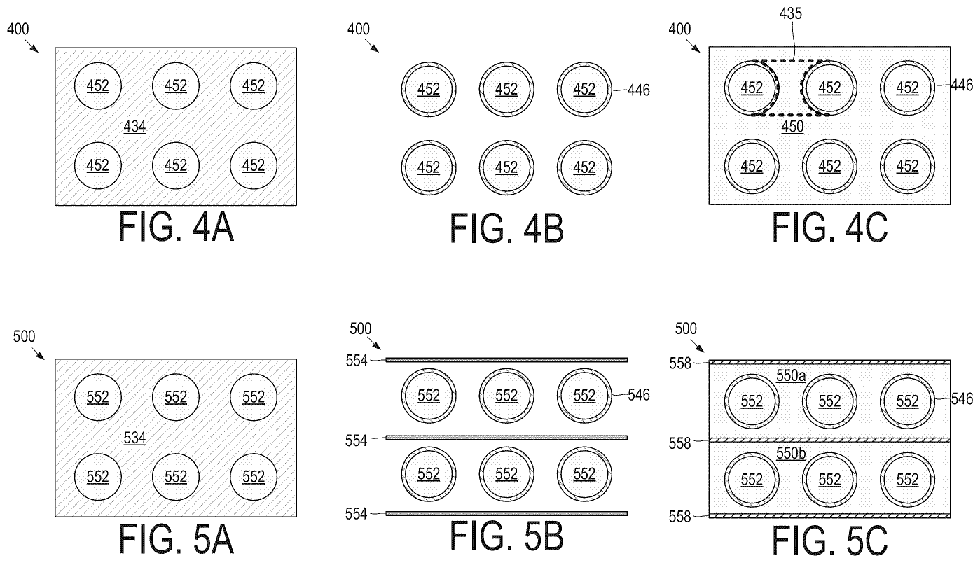

FIGS. 5A-5C illustrate top-down views of a simplified process flow for implementing a second plate line scheme in a memory array employing inverted pillar capacitors. FIGS. 5A-5C illustrate a structure 500 in which a two-by-three array of inverted pillar capacitors will be formed. The capacitors are part of a memory array with the bottom electrode (pillar portion) of each capacitor to operate as the storage node for a memory with a plate line common only to one row of capacitors. FIG. 5A illustrates the structure 500 after formation of pillars 552 in a dielectric 534. FIG. 5A illustrates the same step in the process flow illustrated in FIGS. 3A-3L as FIG. 3D. FIG. 5B illustrates the structure 500 after formation of an insulating layer 546 for the capacitors and after etch of the dielectric 534, and before formation of the metal layer that will form the two top electrodes for the capacitors in the array. The structure 500 in FIG. 5B comprise a plate line lithography pattern 554 that defines where the plate lines will be formed. FIG. 5C illustrates the structure 500 after formation of the metal layer 550 forming the top electrodes for the capacitors in the array. Metal layer 550 comprises portion 550a which is a common top electrode that is to operate as a first plate line for the top row of capacitors and portion 550b which is a common top electrode that is to operate as a second plate line for the bottom row of capacitors. Dielectric regions 558 separate the metal layer portions 550a and 550b from each other, and from other adjacent metal layer portions (not shown).

An integrated circuit component comprising one or more inverted pillar capacitors as disclosed herein can be attached to a printed circuit board. In some embodiments, one or more additional integrated circuit components can be attached to the circuit board. In some embodiments, the printed circuit board and the integrated circuit component can be located in a computing device that comprises a housing that encloses the printed circuit board and the integrated circuit component.

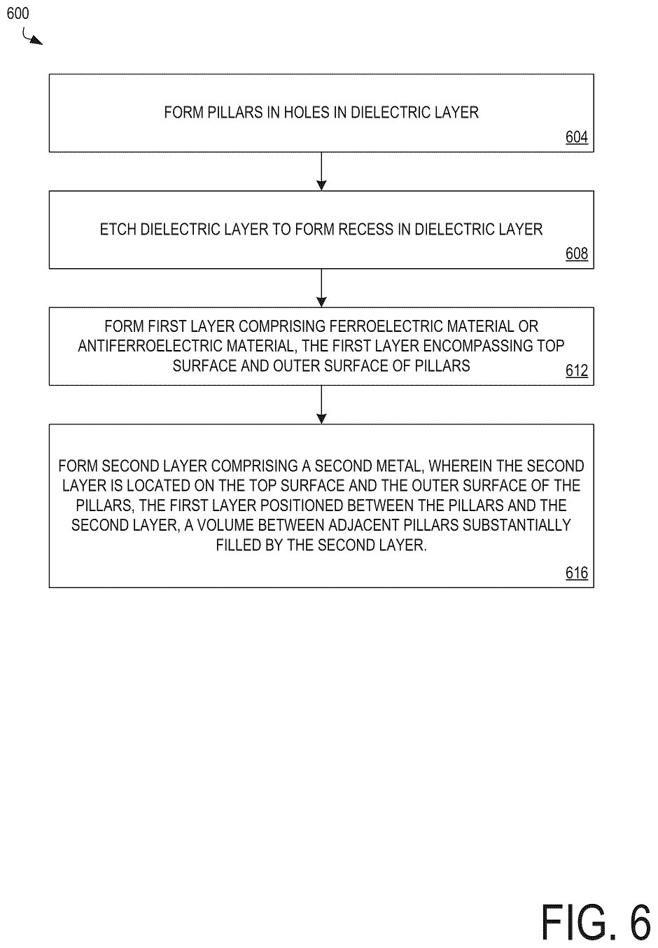

FIG. 6 is an example method of forming an inverted pillar capacitor. The method 600 can be formed by, for example, an integrated circuit component manufacturer. At 604, a plurality of pillars is formed on a substrate, the plurality of pillars formed in holes in a dielectric layer, the plurality of pillars comprising a first metal. At 608, the dielectric layer is etched to form a recess in the dielectric layer, the pillars located in the recess of the dielectric layer. At 612, a first layer comprising a ferroelectric material or an antiferroelectric is formed, the first layer encompassing the top surface and the outer surface of the pillars. At 616, a second layer comprising a second metal is formed, wherein the second layer is located on the top surface and the outer surface of the pillars, the first layer positioned between the pillars and the second layer, wherein the pillars are located with the recess of the dielectric layer, the second layer substantially filling the recess such that a volume between adjacent pillars in the recess is substantially filled by the second layer.

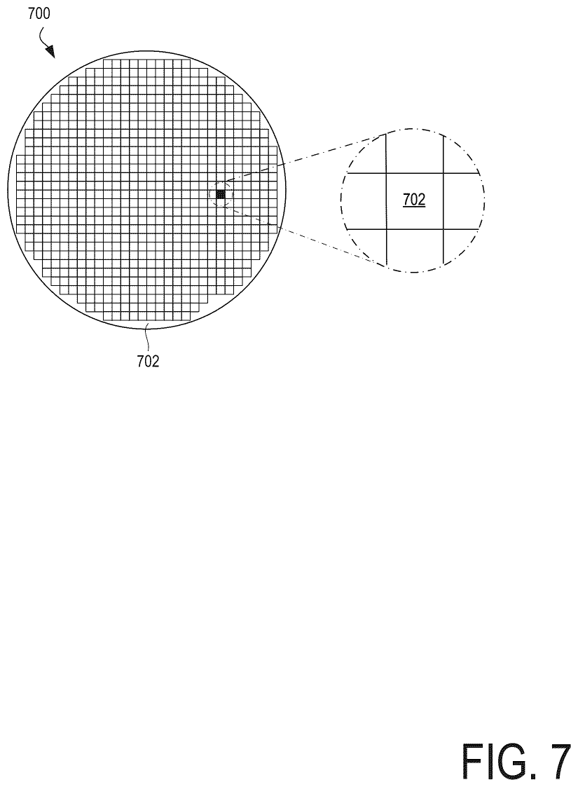

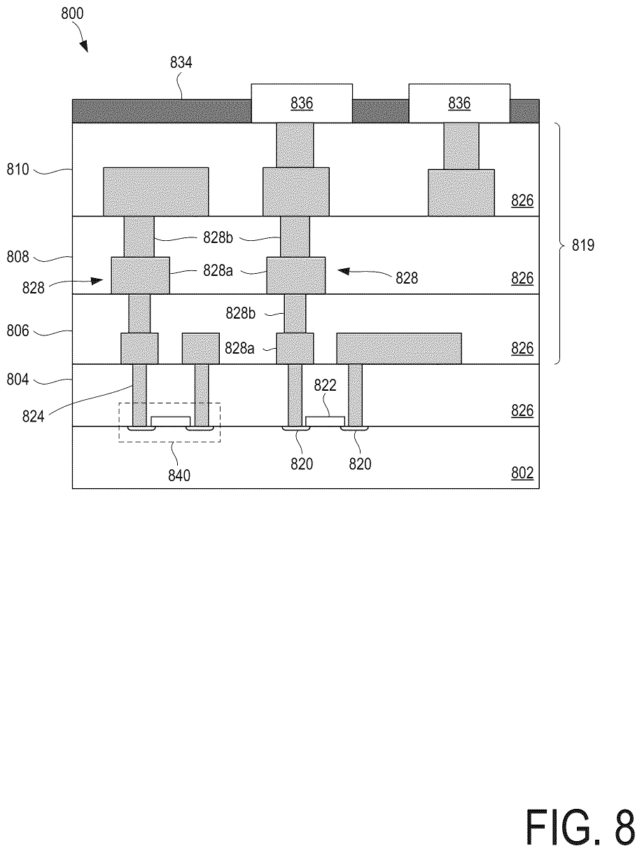

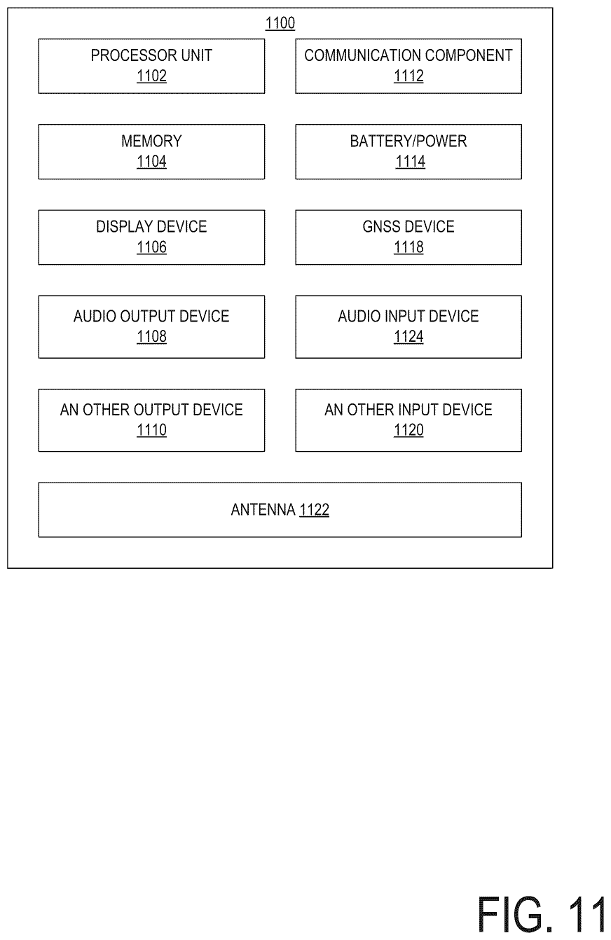

FIG. 7 is a top view of a wafer 700 and dies 702 that may be included in any of the microelectronic assemblies disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may be any of the dies disclosed herein and may comprise any of the inverted pillar capacitors disclosed herein. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1102 of FIG. 11) or other logic that is configured to store information in the memory devices or execute instructions stored in the memory array. Various ones of the microelectronic assemblies disclosed herein may be manufactured using a die-to-wafer assembly technique in which some dies are attached to a wafer 700 that include others of the dies, and the wafer 700 is subsequently singulated.

FIG. 8 is a cross-sectional side view of an integrated circuit device 800 that may be included in any of the microelectronic assemblies disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or silicon-on-insulator (SOI) or silicon-on-sapphire (SOS) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

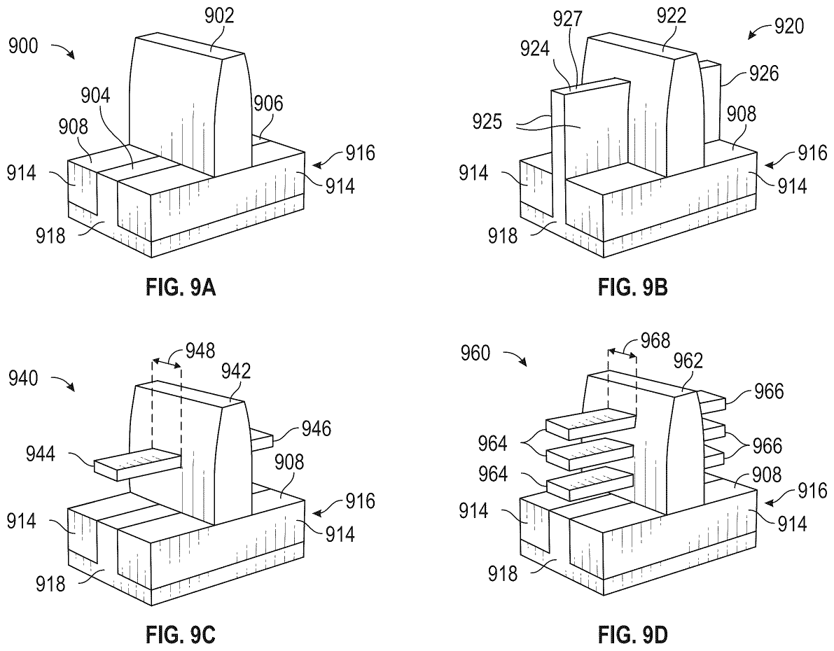

FIGS. 9A-9D are simplified perspective views of example planar, FinFET, gate-all-around, and stacked gate-all-around transistors. The transistors illustrated in FIGS. 9A-9D are formed on a substrate 916 having a surface 908. Isolation regions 914 separate the source and drain regions of the transistors from other transistors and from a bulk region 918 of the substrate 916.

FIG. 9A is a perspective view of an example planar transistor 900 comprising a gate 902 that controls current flow between a source region 904 and a drain region 906. The transistor 900 is planar in that the source region 904 and the drain region 906 are planar with respect to the substrate surface 908.

FIG. 9B is a perspective view of an example FinFET transistor 920 comprising a gate 922 that controls current flow between a source region 924 and a drain region 926. The transistor 920 is non-planar in that the source region 924 and the drain region 926 comprise “fins” that extend upwards from the substrate surface 928. As the gate 922 encompasses three sides of the semiconductor fin that extends from the source region 924 to the drain region 926, the transistor 920 can be considered a tri-gate transistor. FIG. 9B illustrates one S/D fin extending through the gate 922, but multiple S/D fins can extend through the gate of a FinFET transistor.

FIG. 9C is a perspective view of a gate-all-around (GAA) transistor 940 comprising a gate 942 that controls current flow between a source region 944 and a drain region 946. The transistor 940 is non-planar in that the source region 944 and the drain region 946 are elevated from the substrate surface 928.

FIG. 9D is a perspective view of a GAA transistor 960 comprising a gate 962 that controls current flow between multiple elevated source regions 964 and multiple elevated drain regions 966. The transistor 960 is a stacked GAA transistor as the gate controls the flow of current between multiple elevated S/D regions stacked on top of each other. The transistors 940 and 960 are considered gate-all-around transistors as the gates encompass all sides of the semiconductor portions that extends from the source regions to the drain regions. The transistors 940 and 960 can alternatively be referred to as nanowire, nanosheet, or nanoribbon transistors depending on the width (e.g., widths 948 and 968 of transistors 940 and 960, respectively) of the semiconductor portions extending through the gate.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-sectional of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8 The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

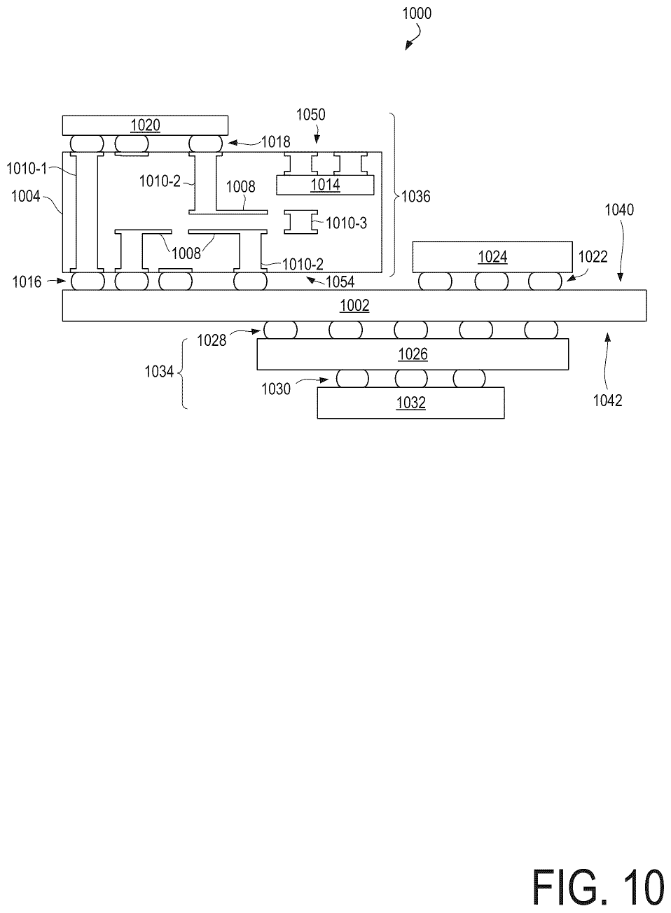

FIG. 10 is a cross-sectional side view of an integrated circuit device assembly 1000 that may include any of the microelectronic assemblies disclosed herein. In some embodiments, the integrated circuit device assembly 1000 may be a microelectronic assembly comprising an integrated circuit component comprises any of the inverted pillar capacitors disclosed herein. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and an opposing second face 1042 of the circuit board 1002; generally, components may be disposed on one or both faces 1040 and 1042. Any of the integrated circuit components discussed below with reference to the integrated circuit device assembly 1000 may take the form of any suitable ones of the embodiments of the microelectronic assemblies disclosed herein.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1016 may serve as the coupling components illustrated or described for any of the substrate assembly or substrate assembly components described herein, as appropriate.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpacked integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art. In embodiments where the interposer is a non-printed circuit board

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a block diagram of an example electrical device 1100 that may include one or more of the microelectronic assemblies disclosed herein. For example, any suitable ones of the components of the electrical device 1100 may include one or more of the integrated circuit device assemblies 1000, integrated circuit components 1020, integrated circuit devices 800, or integrated circuit dies 702 disclosed herein, and may be arranged in any of the microelectronic assemblies disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1100 can comprise one or more processor units 1102 that are heterogeneous or asymmetric to another processor unit 1102 in the electrical device 1100. There can be a variety of differences between the processing units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include an other output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include an other input device 1120 (or corresponding interface circuitry, as discussed above). Examples of the other input device 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

The following examples pertain to additional embodiments of technologies disclosed herein.

Example 1 includes an apparatus comprising a plurality of pillars comprising a first metal, individual of the pillars comprising a top surface and an outer surface; a first layer comprising a ferroelectric material or an antiferroelectric material, the first layer located on the top surface and the outer surface of the pillars; a second layer comprising a second metal, wherein the second layer is located on the top surface and the outer surface of the pillars, the first layer positioned between the pillars and the second layer, wherein the pillars are located within a recess of a dielectric layer, the second layer substantially filling the recess such that a volume between adjacent pillars is substantially filled by the second layer; and a substrate, the pillars located on the substrate.

Example 2 includes the subject matter of Example 1, and wherein the volume between adjacent pillars does not comprise a dielectric material.

Example 3 includes the subject matter of Example 1 or 2, wherein a portion of the first layer encompasses a top surface and an outer surface of one of the pillars, a cross-section of the portion of the first layer having a U-shape that opens toward a surface of the substrate.

Example 4 includes the subject matter of any one of Examples 1-3, wherein the substrate comprises silicon.

Example 5 includes the subject matter of any one of Examples 1-4, wherein a base of one of the pillars is located on and conductively coupled to a surface of the substrate.

Example 6 includes the subject matter of any of Examples 1-5, and wherein the base is conductively coupled to a source region or a drain region of transistor, the source region or the drain region located on a surface region of the substrate and comprising one or more n-type or p-type dopants.

Example 7 includes the subject matter any one of Examples 1-5, wherein the first layer comprises a plurality of portions, individual of the portions physically separate from the other portions, individual of the portions encompassing the top surface and the outer surface of at least one of the pillars.

Example 8 includes the subject matter of any one of Examples 1-7, wherein a thickness of the first layer is in a range of about 1-45 nanometers.

Example 9 includes the subject matter of any one of Examples 1-8, wherein the first metal comprises: copper; tungsten; nickel; molybdenum; or titanium and nitrogen.

Example 10 includes the subject matter of any one of Examples 1-8, wherein the second metal comprises: copper; tungsten; nickel; molybdenum; or titanium and nitrogen.

Example 11 includes the subject matter of any one of Examples 1-8, wherein the first layer comprises a ferroelectric material comprising barium, iron, and oxygen.

Example 12 includes the subject matter of any one of Examples 1-8, wherein the first layer comprises a ferroelectric material comprising lanthanum, barium, iron, and oxygen.

Example 13 includes the subject matter of any one of Examples 1-8, wherein the first layer comprises a ferroelectric material comprising lead, zirconium, titanium, and oxygen.

Example 14 includes the subject matter of any one of Examples 1-8, wherein the first layer comprises a ferroelectric material comprising lead, niobium, zirconium, titanium, and oxygen; lead, lanthanum, zirconium, titanium, and oxygen; lanthanum, bismuth, iron, and oxygen; bismuth, iron, cobalt, and oxygen; lithium, niobium, oxygen; or potassium, niobium, and oxygen.

Example 15 includes the subject matter of any one of Examples 1-8, wherein the first layer comprises a ferroelectric material comprising calcium, niobium, titanium, and oxygen; lead, bismuth, niobium, and oxygen; calcium, niobium, nitrogen, and oxygen, bismuth, titanium, and oxygen, barium, hafnium, titanium, and oxygen; barium, calcium, zirconium, titanium, and oxygen; gadolinium, iron, and oxygen; or gadolinium, lanthanum, iron, and oxygen.

Example 16 includes the subject matter of any one of Examples 1-8, wherein the first layer comprises an antiferroelectric material comprising hafnium, oxygen, and zirconium.

Example 16.1 includes the subject matter of any one of Examples 1-8, wherein the first layer comprises a ferroelectric material comprising hafnium, oxygen, and zirconium.

Example 17 includes the subject matter of any one of Examples 1-8, wherein the first layer comprises an antiferroelectric material comprising hafnium; oxygen; and one or more of silicon, aluminum, yttrium, gadolinium, germanium, lead, zirconium, titanium, tin, strontium, lanthanum, and niobium.

Example 18 includes the subject matter of any one of Examples 1-8, wherein the first layer comprises silicon and oxygen; silicon, oxygen, and carbon; silicon, oxygen, and fluorine; silicon, oxygen, and hydrogen; or silicon and nitrogen.

Example 19 includes the subject matter of any one of Examples 1-18, wherein one of the pillars is a bottom electrode of a capacitor, a portion of the first layer encompassing the top surface and the outer surface of the one of the pillars is an insulator of the capacitor, and a portion of the second layer positioned adjacent to the portion of the first layer is a second electrode of the capacitor.

Example 20 includes the subject matter of any one of Examples 1-19, wherein the apparatus is located in an integrated circuit component.

Example 21 includes the subject matter of any one of Examples 1-20, wherein the apparatus further comprises one or more transistors.

Example 22 includes the subject matter of any one of Examples 1-19, wherein the apparatus comprises a printed circuit board; and a first integrated circuit component attached to the printed circuit board, the first integrated circuit component comprising the pillars, the first layer, and the second layer.

Example 23 includes the subject matter of any of Examples 1-22, and wherein the apparatus further comprises one or more second integrated circuit components attached to the printed circuit board.

Example 24 includes the subject matter of any of Examples 1-23, and wherein the apparatus further comprises a housing enclosing the printed circuit board and the first integrated circuit component.

Example 25 includes a method comprising forming, on a substrate, a plurality of pillars in holes in a dielectric layer, the plurality of pillars comprising a first metal; etching the dielectric layer to form a recess in the dielectric layer, the pillars located in the recess of the dielectric layer; forming a first layer comprising a ferroelectric material or an antiferroelectric material, the first layer encompassing a top surface and an outer surface of individual of the pillars; and forming a second layer comprising a second metal, wherein the second layer is located on the top surface and the outer surface of the pillars, the first layer positioned between the pillars and the second layer, wherein the pillars are located with the recess of the dielectric layer, the second layer substantially filling the recess such that a volume between adjacent is substantially filled by the second layer.

Example 26 includes the subject matter of Example 25, and wherein the volume between adjacent pillars does not comprise a dielectric material.

Example 27 includes the subject matter of Example 25 or 26, wherein a portion of the first layer encompasses a top surface and an outer surface of the one of the pillars, a cross-section of the portion of the first layer having a U-shape that opens toward a surface of the substrate.

Example 28 includes the subject matter of any one of Examples 25-27, wherein the substrate comprises silicon.

Example 29 includes the subject matter of any one of Examples 25-28, wherein a base of one of the pillars is located on and conductively coupled to a surface of the substrate.

Example 30 includes the subject matter of any one of Examples 25-29, wherein the first layer comprises a plurality of portions, individual of the portions physically separate from the other portions, the individual portions encompassing the top surface and the outer surface of at least one of the pillars.

Example 31 includes the subject matter of any one of Examples 25-30, wherein a thickness of the second layer is in a range of about 1-45 nanometers.

Example 32 includes the subject matter of any one of Examples 25-31, wherein the first metal comprises copper, tungsten, or nickel.

Example 33 includes the subject matter of any one of Examples 25-31, wherein the second metal comprises copper, tungsten, or nickel.

Example 34 includes the subject matter of any one of Examples 25-31, wherein the first layer comprises a ferroelectric material comprising barium, iron, and oxygen.

Example 35 includes the subject matter of any one of Examples 25-31, wherein the first layer comprises a ferroelectric material comprising lanthanum, barium, iron, and oxygen.

Example 36 includes the subject matter of any one of Examples 25-31, wherein the first layer comprises a ferroelectric material comprising lead, zirconium, titanium, and oxygen.

Example 37 includes the subject matter of any one of Examples 25-31, wherein the first layer comprises a ferroelectric material comprising lead, niobium, zirconium, titanium, and oxygen; lead, lanthanum, zirconium, titanium, and oxygen; lanthanum, bismuth, iron, and oxygen; bismuth, iron, cobalt, and oxygen; lithium, niobium, oxygen; or potassium, niobium, and oxygen.

Example 38 includes the subject matter of any one of Examples 25-31, wherein the first layer comprises a ferroelectric material comprising calcium, niobium, titanium, and oxygen; lead, bismuth, niobium, and oxygen; calcium, niobium, nitrogen, and oxygen, bismuth, titanium, and oxygen, barium, hafnium, titanium, and oxygen; barium, calcium, zirconium, titanium, and oxygen; gadolinium, iron, and oxygen; or gadolinium, lanthanum, iron, and oxygen.

Example 38.1 includes the subject matter of any one of Examples 25-31, wherein the first layer comprises an antiferroelectric material comprising hafnium, oxygen, and zirconium.

Example 39 includes the subject matter of any one of Examples 25-31, wherein the first layer comprises an antiferroelectric material comprising hafnium, oxygen, and zirconium.

Example 40 includes the subject matter of any one of Examples 25-31, wherein the first layer comprises a ferroelectric material comprising hafnium; oxygen; and one or more of silicon, aluminum, yttrium, gadolinium, germanium, lead, zirconium, titanium, tin, strontium, lanthanum, and niobium.

Example 41 includes the subject matter of any one of Examples 25-31, wherein the dielectric layer comprises silicon and oxygen; silicon, oxygen, and carbon; silicon, oxygen, and fluorine; silicon, oxygen, and hydrogen; or silicon and nitrogen.

Example 42 includes the subject matter of any one of Examples 25-41, wherein one of the pillars is a first electrode of a capacitor, a portion of the first layer encompassing the top surface and the outer surface of the one of the pillars is an insulator of the capacitor, and a portion of the second layer positioned adjacent to the portion of the first layer is a second electrode of the capacitor.

1. An apparatus comprising:
a plurality of pillars comprising a first metal, individual of the pillars comprising a top surface and an outer surface;
a first layer comprising a ferroelectric material or an antiferroelectric material, the first layer located on the top surface and the outer surface of the pillars;
a second layer comprising a second metal, wherein the second layer is located on the top surface and the outer surface of the pillars, the first layer positioned between the pillars and the second layer, wherein the pillars are located within a recess of a dielectric layer, the second layer substantially filling the recess such that a volume between adjacent pillars is substantially filled by the second layer; and
a substrate, the pillars located on the substrate.

2. The apparatus of claim 1, wherein the volume between adjacent pillars does not comprise a dielectric material.

3. The apparatus of claim 1, wherein a portion of the first layer encompasses a top surface and an outer surface of one of the pillars, a cross-section of the portion of the first layer having a U-shape that opens toward a surface of the substrate.

4. The apparatus of claim 1, wherein the substrate comprises silicon.

5. The apparatus of claim 1, wherein a base of one of the pillars is located on and conductively coupled to a surface of the substrate.

6. The apparatus of claim 5, wherein the base is conductively coupled to a source region or a drain region of transistor, the source region or the drain region located on a surface region of the substrate and comprising one or more n-type or p-type dopants.

7. The apparatus of claim 1, wherein the first layer comprises a plurality of portions, individual of the portions physically separate from the other portions, individual of the portions encompassing the top surface and the outer surface of at least one of the pillars.

8. The apparatus of claim 1, wherein a thickness of the first layer is in a range of about 1-45 nanometers.

9. The apparatus of claim 1, wherein the first metal comprises:
copper;
tungsten;
nickel;
molybdenum; or
titanium and nitrogen.

10. The apparatus of claim 1, wherein the second metal comprises:
copper;
tungsten;
nickel;
molybdenum; or
titanium and nitrogen.

11. The apparatus of claim 1, wherein the first layer comprises a ferroelectric material comprising barium, iron, and oxygen.

12. The apparatus of claim 1, wherein the first layer comprises a ferroelectric material comprising lanthanum, barium, iron, and oxygen.

13. The apparatus of claim 1, wherein the first layer comprises a ferroelectric material comprising lead, zirconium, titanium, and oxygen.

14. The apparatus of claim 1, wherein the first layer comprises a ferroelectric material comprising:
lead, niobium, zirconium, titanium, and oxygen;
lead, lanthanum, zirconium, titanium, and oxygen;
lanthanum, bismuth, iron, and oxygen;
bismuth, iron, cobalt, and oxygen;
lithium, niobium, oxygen; or
potassium, niobium, and oxygen.

15. The apparatus of claim 1, wherein the first layer comprises a ferroelectric material comprising:
calcium, niobium, titanium, and oxygen;
lead, bismuth, niobium, and oxygen;
calcium, niobium, nitrogen, and oxygen,
bismuth, titanium, and oxygen,
barium, hafnium, titanium, and oxygen;
barium, calcium, zirconium, titanium, and oxygen;
gadolinium, iron, and oxygen; or
gadolinium, lanthanum, iron, and oxygen.

16. The apparatus of claim 1, wherein the first layer comprises a ferroelectric material comprising hafnium, oxygen, and zirconium.

17. The apparatus of claim 1, wherein the first layer comprises an antiferroelectric material comprising hafnium, oxygen, and zirconium.

18. The apparatus of claim 1, wherein the first layer comprises a ferroelectric material comprising:
hafnium;
oxygen; and
one or more of silicon, aluminum, yttrium, gadolinium, germanium, lead, zirconium, titanium, tin, strontium, lanthanum, and niobium.

19. The apparatus of claim 1, wherein the first layer comprises:
silicon and oxygen;
silicon, oxygen, and carbon;
silicon, oxygen, and fluorine;
silicon, oxygen, and hydrogen; or
silicon and nitrogen.

20. The apparatus of claim 1, wherein one of the pillars is a bottom electrode of a capacitor, a portion of the first layer encompassing the top surface and the outer surface of the one of the pillars is an insulator of the capacitor, and a portion of the second layer positioned adjacent to the portion of the first layer is a second electrode of the capacitor.

21. The apparatus of claim 1, wherein the apparatus is located in an integrated circuit component.

22. The apparatus of claim 1, wherein the apparatus comprises:
a printed circuit board; and
a first integrated circuit component attached to the printed circuit board, the first integrated circuit component comprising the pillars, the first layer, and the second layer.

23. A method comprising:
forming, on a substrate, a plurality of pillars in holes in a dielectric layer, the plurality of pillars comprising a first metal;
etching the dielectric layer to form a recess in the dielectric layer, the pillars located in the recess of the dielectric layer;
forming a first layer comprising a ferroelectric material or an antiferroelectric material, the first layer encompassing a top surface and an outer surface of individual of the pillars; and
forming a second layer comprising a second metal, wherein the second layer is located on the top surface and the outer surface of the pillars, the first layer positioned between the pillars and the second layer, wherein the pillars are located with the recess of the dielectric layer, the second layer substantially filling the recess such that a volume between adjacent is substantially filled by the second layer.

24. The method of claim 23, wherein the volume between adjacent pillars does not comprise a dielectric material.

25. The method of claim 23, wherein a portion of the first layer encompasses a top surface and an outer surface of the one of the pillars, a cross-section of the portion of the first layer having a U-shape that opens toward a surface of the substrate.
